(19) United States
(12) Patent Application Publication
(10) Pub. No.: US 2002/0034868 A1
(43) Pub. Date: Mar. 21, 2002

(54) Semiconductor device having a gate and fabrication method therefor

(75) Inventors: Ji Soo Park, Chungcheongbuk-do (KR); Dong Kyun Sohn, Chungcheongbuk-do (KR)

Correspondence Address: BIRCH STEWART KOLASCH & BIRCH, PO BOX 747, FALLS CHURCH, VA, 22040-0747, US

(73) Assignee: Hyundai Micro Electronics Co., Ltd.

(21) Appl. No.: 09/998,131

(22) Filed: Dec. 3, 2001

Related U.S. Application Data
(63) Continuation of application No. 09/377,495, filed on Aug. 20, 1999.

(30) Foreign Application Priority Data
Oct. 9, 1998 (KR) 42340/1998

(51) Int. Cl. H01L 21/44; H01L 21/3205

(52) U.S. Cl. 438/592; 438/652; 438/656; 438/660; 438/683

(57) ABSTRACT

A semiconductor device having a gate and a fabrication method therefor is disclosed, which can improve a thermal stability, has a low resistance, and assure an easy fabrication process. The fabrication method includes the steps of (1) forming a first insulating film and a conductive film on a semiconductor substrate, (2) patterning the first insulating film and a conductive film on a semiconductor substrate, (2) patterning the first insulating film and the conductive film, to form a gate, (3) forming a second insulating film thicker than the gate on an entire surface, (4) planarizing the second insulating film, to expose the gate, (5) depositing a refractory metal layer on an entire surface, (6 ) forming a silicide layer on an upper surface of the gate by heat treatment, and (7) etching the refractory metal layer and the second insulating film.

### BACKGROUND OF THE INVENTION

1. Field of the Invention

The present invention relates to a semiconductor device having a gate and a fabrication method therefor which improve thermal stability, lower resistance and simply fabrication.

2. Background of the Related Art

A related art method for forming a gate electrode in a semiconductor device will be explained with reference to the attached drawings. FIGS. 1A˜1C are sectional views of a semiconductor device during fabrication, which figures illustrate the steps of a related art method for forming a gate electrode. The high gate resistance caused by miniturization of the semiconductor device decreases the device operation speed. Consequently, a gate electrode with a low resistance is required. To meet such a requirement, a refractory metal silicide having a low resistance is employed for the gate electrode. This refractory metal silicide is called a polycide (silicide on doped polycrystalline-Si). Of the polycides, WSi₂ (resistivity 60˜200 μΩ/cm) is the most widely used. However, a polycide having a resistance lower than that of the WSi₂ is CoSi₂ (resistivity 15˜20 μΩ/cm) and TiSi₂ (resistivity 15˜20 μΩ/cm).

First, a thermal process conducted after formation of a silicide agglomerates the silicide, with an increased resistance. CoSi₂ shows an excellent thermal stability with less agglomeration than TiSi₂. (J. B. Lasky et al. IEEE Trans. Elec. Dev., 38, 262(1991), L. Vanden hove, VLSI tecnol., (1987). P.67).

Referring to FIG. 1A, in the method for forming a gate electrode of such a refractory metal, a gate oxide film 2 is formed on the semiconductor substrate 1. A polysilicon layer 3, a silicide layer 4, and an insulating layer 5 are then stacked on the gate oxide film 2 in succession, insulating layer 5 being used as a hard mask. As shown in FIG. 1B, the insulating layer 5 is subjected to patterning by photolithography, and the silicide layer 4 and the polysilicon layer 3 are subjected to selective patterning by a dry etching process using the patterned insulating layer 5 as a mask, thereby forming a gate electrode layer 6. As shown in FIG. 1C, an insulating layer for forming gate sidewalls is deposited on an entire surface including the gate electrode layer 6. The insulating layer is etched back to form sidewalls 7 located only at the sides of the gate electrode layer 6. In this instance, the refractory metal is Co or Ti.

Of CoSi₂ and TiSi₂, which have similar resistivities, CoSi₂ has conventionally been preferred for formation of the gate electrode for at least the following reasons.

First, a thermal process conducted after formation of a silicide agglomerates the silicide, with an increased resistance. CoSi₂ shows an excellent thermal stability with a less agglomeration than TiSi₂.(J. B. Lasky et al. IEEE Trans.

Elec. Dev., 38, 262(1991), L. Vanden hove, VLSI tecnol., (1987). P.67).

Second, in comparison to a sharp increase in resistance in the case of TiSi₂ when the width of the gate line is reduced, the resistance of CoSi₂ is kept low even if the gate line width is reduced.

Third, CoSi₂ may be used as SADS(Silicide as A Dopant Source) for easy doping of polysilicon. SADS is a method for doping a silicon layer by heating, and diffusing dopant injected in a silicide into an underlying silicon layer. Though CoSi₂ can be used as SADS, TiSi₂ can not be used as SADS, because TiSi₂ has a high reactivity with dopants like As, P, and B. (K. Maex et al., J. Appl. Phys., 66, 5327(1989), V. Probst et al., J. Appl. Phys., 52, 1803(1988), F. C. Shone et al., Int. Elec. Dev. Meet., (1986), p. 407).

Because of the properties of CoSi₂, attempts have been made to form the gate electrode of CoSi₂.

However, despite of its advantage of low resistance, the related art method for forming a gate electrode of a refractory metal silicide has at least the following problems related to etching. CoSi₂ is difficult to etch, causing problems in patterning a gate line. (F. Fracassi et al., J. Electrochem. Soc., 143.701(1996)). Though etching by converting into TiF or TiC12, which are volatile, is widely used in the case of TiSi₂ in a dry etching(T. P. Chow et al., in Dry Etching for Microelectronics, R. A. Powell, Editor, p. 40, Elsevier Science, New York (1984)), as cobalt is very stable without any volatile chemical compounds, etching of cobalt is very difficult. (A. E. Morgan et al., J. Electrochem. Soc., 134, 925(1987)).

### SUMMARY OF THE INVENTION

The present invention is directed to a semiconductor device having a gate and a fabrication method therefor that substantially obviate one or more of the problems due to limitations and disadvantages of the related art.

An object of the present invention is to provide a semiconductor device having a gate and fabrication method therefor, which result in improved thermal stability, low resistance, and simplified fabrication.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, the method for forming a gate in a semiconductor device, for improving a thermal stability, providing a low resistance, and assuring an easy fabrication process, may include (1) forming a first insulating film and a conductive film on a semiconductor substrate, (2) patterning the first insulating film and the conductive film, to form a gate, (3) forming a second insulating film thicker than the gate on an entire surface, (4) planarizing the second insulating film, to expose the gate, (5) depositing a refractory metal layer on an entire surface, (6) forming a silicide layer on an upper surface of the gate by heat treatment, and (7) etching the refractory metal layer and the second insulating film.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIGS. 1A˜1C illustrate sectional views of a semiconductor device showing steps of a related art method for forming a gate electrode; and, FIGS. 2A˜2G illustrate sectional views of a semiconductor device showing steps of a method for forming a gate electrode in accordance with a preferred embodiment of the present invention, FIG. 2G showing the completed semiconductor device having the gate electrode formed in accordance with the present invention.

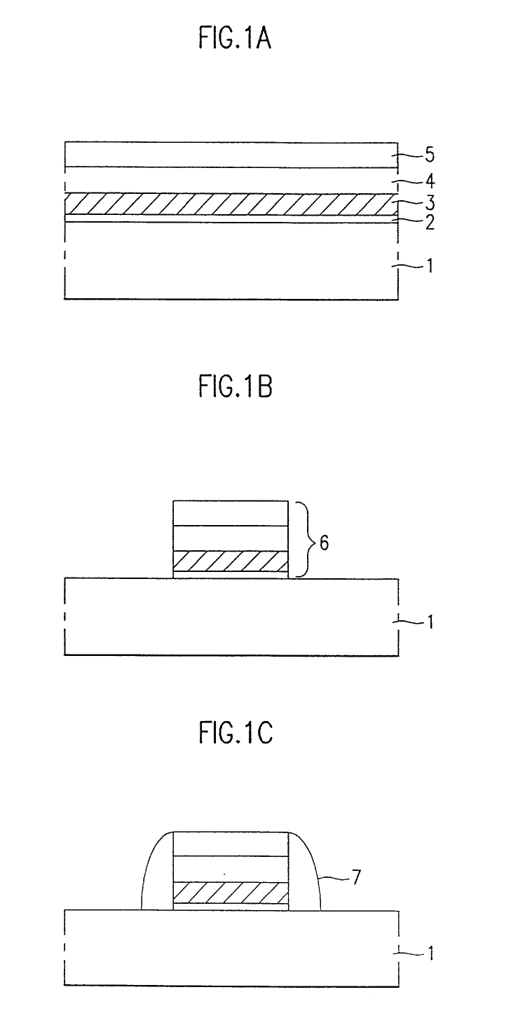

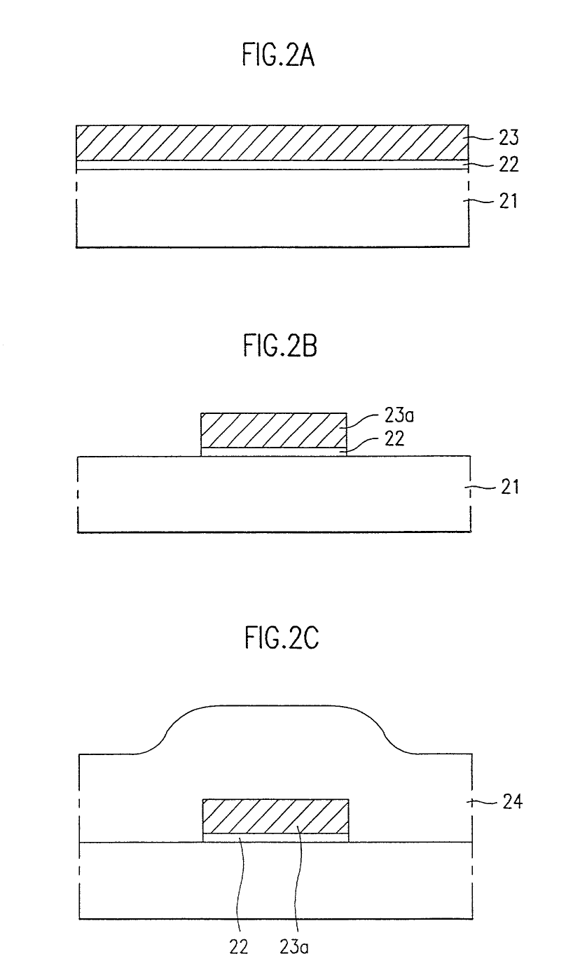

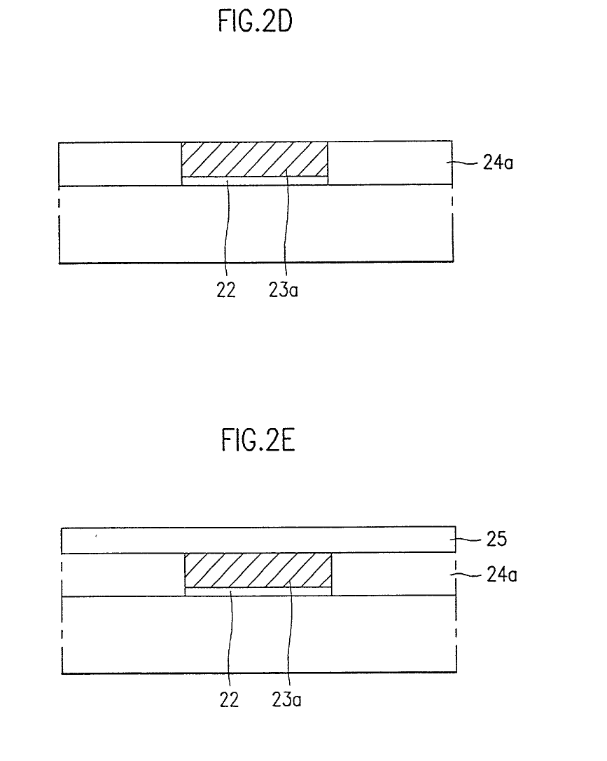

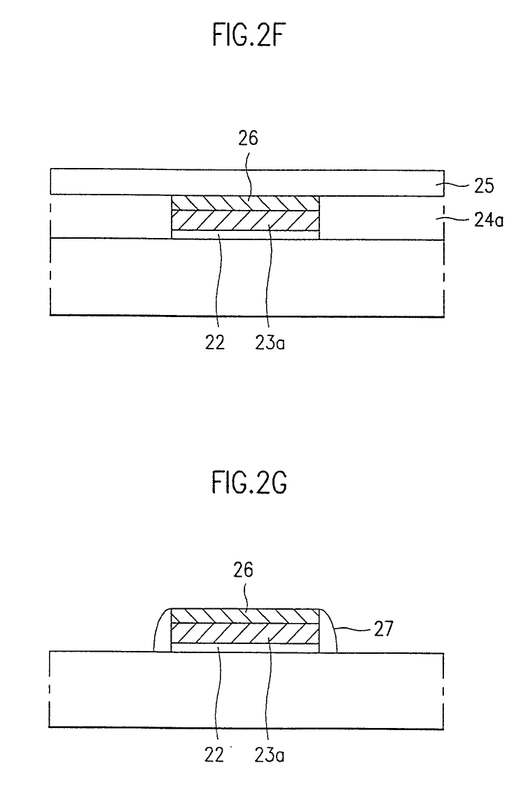

### DETAILED DESCRIPTION OF THE PREFERRED EMBODIMENT

Reference will now be made in detail to the preferred embodiments of the present invention, examples of which are illustrated in the accompanying drawings. FIGS. 2A˜2G illustrate sectional views of a semiconductor device showing steps of a method for forming a gate electrode in accordance with a preferred embodiment of the present invention. The present invention assures an easy fabrication process in forming a CoSi₂ gate electrode which has a good thermal stability and a low resistance.

Referring to FIG. 2A, the method for forming a gate electrode in accordance with a preferred embodiment of the present invention starts with forming a gate oxide film 22 on a semiconductor substrate 21, and forming a material layer 23 for forming a gate, for example, a conductive film, such as a polysilicon layer, to a thickness of 2500A (±5%). As shown in FIG. 2B, material layer 23 is selectively patterned to form a material pattern layer 23a for forming a gate. Then, as shown in FIG. 2C, an insulating layer 24, for example, an oxide film or a nitride film, is formed to a thickness of 2500˜3500A on an entire surface including the material pattern layer 23a for forming a gate. As shown in FIG. 2D, the insulating layer 24 is planarized by CMP (Chemical Mechanical Polishing), to expose a top surface of the material pattern layer 23a for forming a gate, (the planarized insulating layer is identified as 24a). Then, as shown in FIG. 2E, a refractory metal layer 25, for example, a Co layer, is formed to a thickness of 300A (±5%) on the planarized insulating layer 24a and the material pattern layer 23a for forming a gate. And, as shown in FIG. 2F, a silicide layer 26, for example, a CoSi₂ layer, is formed by a thermal treatment process at an interface of the refractory metal layer 25 and the material pattern layer 23a for forming a gate. As shown in FIG. 2G, after silicide layer 26 has been formed, the portion of refractory metal layer 25 that [made no reaction] has not reacted due to the planarized insulating layer 24a is wet etched. To wet etch the refractory metal layer 25, a H₂SO₄ or HCl-based solution is used. Then, as also shown in FIG. 2G, the planarized insulating layer 24a is removed. An insulating film is thereafter again deposited on an entire surface and etched back to leave insulating film at sides of the gate electrode, thereby forming gate sidewalls 27. In this instance, the gate electrode has a total thickness of approximately 2000A (±5%), with a polysilicon layer of a 1000A (±5%) thickness, excluding a loss portion during the silicide reaction and the silicide layer thickness of approximately 1000A (±5%).

Thus, the method for forming a gate electrode of CoSi₂ in the present invention allows formation of the gate electrode without a separate silicide layer patterning process, by patterning a polysilicon layer, which is a lower layer of the gate electrode, before making a silicide reaction only on the patterned polysilicon layer.

The method for forming a gate electrode of CoSi₂ using the concepts the present invention has at least the following advantages.

First, CoSi₂ can be used as a polycide despite its poor etchability. That is, the method for forming a gate electrode of CoSi₂ of the present invention allows formation of the gate electrode without a separate silicide layer patterning process, by patterning a polysilicon layer that is positioned as a lower layer of the gate electrode before a silicide reaction occurs, thereby limiting the silicide reaction to the patterned polysilicon layer and assuring an easy fabrication process.

Second, because no separate silicide layer patterning is performed, no etching damage is experienced, eliminating the need for an oxidation process ordinarily required for recovering the damage to the gate oxide film. Because the silicide is not oxidized in this manner, a loss of Si can be prevented.

Third, the formation of the silicide, not in source/drain regions, but only in the gate electrode layer, solves the problem of junction leakage in the source/drain regions.

It will be apparent to those skilled in the art that various modifications and variations can be made in the method for forming a gate in a semiconductor device of the present invention without departing from the spirit or scope of the invention. Thus, it is intended that the present invention cover the modifications and variations of this invention provided they come within the scope of the appended claims and their equivalents.

What is claimed is:

1. A method for forming a gate in a semiconductor device, comprising:
forming a first insulating film and a non-silicide conductive film on a semiconductor substrate;
patterning the first insulating film and the conductive film, to form a gate;
forming a second insulating film thicker than the gate on an entire surface;
planarizing the second insulating film, to expose the gate;
depositing a refractory metal layer on an entire surface such that the refractory metal layer is adjacent to the patterned conductive film;
forming a silicide layer on an upper surface of the gate by heat treatment; and
etching the refractory metal layer and the second insulating film.

2. A method as claimed in claim 1, wherein the refractory metal layer is formed of cobalt.

3. A method as claimed in claim 2, wherein the cobalt is deposited to a thickness of 300 Å.

4. A method as claimed in claim 1, further comprising forming gate sidewalls by depositing and etching back an insulating layer after etching the second insulating film to leave an insulating film at sides of the gate.

5. A method as claimed in claim 1, wherein the conductive film is a polysilicon layer.

6. A method as claimed in claim 5, wherein the polysilicon layer has a thickness of 2500 Å.

7. A method as claimed in claim 1, wherein the heat treatment for forming the silicide layer is conducted at a temperature of 400˜800° C.

8. A method as claimed in claim 1, wherein the refractory metal layer that does not react is wet etched using H₂SO₄ or HCl-based solution to remove the refractory metal layer.

9. A method as claimed in claim 1, wherein the planarizing includes a chemical mechanical polishing process.

10. A method of fabricating a gate in a semiconductor device, comprising:
forming a non-silicide conductive pattern on a semiconductor substrate; and
forming a silicide pattern on the conductive pattern, the silicide pattern having a predetermined width, and being formed after the conductive pattern is formed, said step of forming a silicide pattern comprising:
forming a refractory metal on the conductive pattern such that the refractory metal is adjacent to the conductive pattern; and
heat treating the refractory metal to form the silicide pattern having the predetermined width at an intersection between the refractory metal and the conductive pattern.

11. The method of claim 10, wherein the conductive pattern is formed of polysilicon.

12. The method of claim 11, wherein the polysilicon pattern has a thickness of 2500 angstroms.

13. The method of claim 1, wherein forming the polysilicon pattern comprises:
forming a polysilicon layer on the semiconductor substrate; and
etching the polysilicon layer to the predetermined width.

14. The method of claim 13, further comprising:
forming an insulating layer on and around the polysilicon pattern; and
planarizing the insulating layer to expose a surface of the polysilicon pattern before forming the refractory metal on the polysilicon layer.

15. The method of claim 14, wherein the refractory metal is cobalt.

16. The method of claim 15, wherein the cobalt is deposited to a thickness of 300 angstroms.

17. The method of claim 13, further comprising:
forming a gate insulating layer on the semiconductor substrate, the polysilicon layer being formed on the gate insulating layer; and
forming a gate insulating pattern by etching the gate insulating layer to the predetermined width.

18. The method of claim 17, wherein the polysilicon layer and the gate insulating layer are respectively etched to form the polysilicon pattern and the gate insulating pattern before the silicide pattern is formed.

19. The method of claim 18, wherein sides of the gate insulating layer, the polysilicon pattern and the silicide pattern are aligned orthogonal to a surface of the semiconductor substrate on which the gate insulating film is formed.

20. The method of claim 19, further comprising:
forming a gate sidewall on at least one side of the gate insulating layer, the polysilicon pattern and the silicide pattern.

21. A method of fabricating a gate electrode of a predetermined width, comprising:
forming a gate insulating layer on a semiconductor substrate; and
forming a silicide pattern on the gate insulating layer without etching a silicide from which the silicide pattern is fabricated.
